(19) United States
(12) Patent Application Publication
(10) Pub. No.: US 2026/0342320 A1
(43) Pub. Date: Oct. 29, 2026

(54) DIGITALLY SYNCHRONIZING AN INACCURATE INTERNAL CLOCK TO A SYNCHRONIZATION CLOCK WHILE MAINTAINING A TARGET DUTY-CYCLE

(71) Applicant: Raytheon Company, Arlington, VA (US)

(72) Inventors: Amir Rahimi, Mission Viejo, CA (US); Stanley S. Yue, La Canada, CA (US); Long C. Tran, Huntington Beach, CA (US); Jorge Rodriguez, Downey, CA (US); David Huy-Kim Do, Garden Grove, CA (US); William Lin, Temple City, CA (US)

(21) Appl. No.: 19/189,921

(22) Filed: Apr. 25, 2025

(51) Int. Cl. H03K 5/08; H03K 7/08; H03K 21/08

(52) U.S. Cl. CPC H03K 5/084; H03K 7/08; H03K 21/08

(57) ABSTRACT

A method of tuning of clock synchronization includes generating a preliminary synchronization clock signal based on a synchronization clock signal, wherein a switching frequency of the preliminary synchronization clock signal is less than a switching frequency of the synchronization clock signal. The method includes determining, by a digital controller, a quantity of pulses of a high-frequency internal clock signal which fit within a first time period during which the preliminary synchronization clock signal is generated. The method includes providing the synchronization clock signal to the digital controller during a second time period different from the first time period. The method includes generating, by the digital controller, a clock signal based on the high-frequency internal clock signal and the quantity of pulses, during the second time period.

### BACKGROUND

The present disclosure relates to digitally synchronizing an internal clock to a synchronization clock (also referred to herein as a ‘sync clock’), and particularly, digitally synchronizing internal clocks of components (e.g., power converters) included in a power electronic system to the synchronization clock. Particularly, the present disclosure relates to digitally synchronizing a non-accurate internal clock to a sync clock while maintaining a target duty cycle, for example, a duty-cycle relatively close to 50%.

In an electronic system in which several components are operating at the same time or in parallel, an external synchronization clock may be provided to the components by an upper system. Techniques for effectively synching the internal clock of each of the components to the synchronization clock are desired.

### SUMMARY

Example embodiments of the present disclosure are directed to a method of tuning of clock synchronization including: generating a preliminary synchronization clock signal based on a synchronization clock signal, wherein a switching frequency of the preliminary synchronization clock signal is less than a switching frequency of the synchronization clock signal; determining, by a digital controller, a quantity of pulses of a high-frequency internal clock signal which fit within a first time period during which the preliminary synchronization clock signal is generated; providing the synchronization clock signal to the digital controller during a second time period different from the first time period; and generating, by the digital controller, a clock signal based on the high-frequency internal clock signal and the quantity of pulses, during the second time period.

In any one or combination of the embodiments disclosed herein, generating the preliminary synchronization clock signal includes: providing the synchronization clock signal to a digital counter during the first time period; and generating, by the digital counter, the preliminary synchronization clock signal during the first time period.

In any one or combination of the embodiments disclosed herein, the method further includes maintaining or modifying the clock signal based on a frequency of the synchronization clock signal.

In any one or combination of the embodiments disclosed herein, the method further includes during the second time period, adjusting a frequency of the clock signal such that a duty cycle of a second clock signal derived from synchronizing the clock signal and the synchronization clock signal is about 50 percent.

In any one or combination of the embodiments disclosed herein, the method further includes providing the clock signal to a full bridge power converter.

In any one or combination of the embodiments disclosed herein, a frequency of the clock signal is less than a frequency of the synchronization clock signal.

In any one or combination of the embodiments disclosed herein, the method further includes: calculating a divide-by value based on which to divide the high-frequency internal clock signal, based on the quantity of pulses, wherein generating the clock signal includes dividing the high-frequency internal clock signal by the divide-by value.

In any one or combination of the embodiments disclosed herein, generating the clock signal is further based on a target timing difference between a rising edge of the synchronization clock signal and a rising edge of the clock signal.

Example embodiments of the present disclosure are directed to a system configured to: generate a preliminary synchronization clock signal based on a synchronization clock signal, wherein a switching frequency of the preliminary synchronization clock signal is less than a switching frequency of the synchronization clock signal; determine, by a digital controller included in the system, a quantity of pulses of a high-frequency internal clock signal which fit within a first time period during which the preliminary synchronization clock signal is generated; provide the synchronization clock signal to the digital controller during a second time period different from the first time period; and generate a clock signal based on the high-frequency internal clock signal and the quantity of pulses, during the second time period.

In any one or combination of the embodiments disclosed herein, the system is configured to generate the preliminary synchronization clock signal by: providing the synchronization clock signal to a digital counter during the first time period; and generating, by the digital counter, the preliminary synchronization clock signal during the first time period.

In any one or combination of the embodiments disclosed herein, the system is configured to maintain or modify the clock signal based on a frequency of the synchronization clock signal.

In any one or combination of the embodiments disclosed herein, the system is configured to, during the second time period, adjust a frequency of the clock signal such that a duty cycle of a second clock signal derived from synchronizing the clock signal and the synchronization clock signal is about 50 percent.

In any one or combination of the embodiments disclosed herein, the system is configured to provide the clock signal to a full bridge power converter.

In any one or combination of the embodiments disclosed herein, a frequency of the clock signal is less than a frequency of the synchronization clock signal.

In any one or combination of the embodiments disclosed herein, the system is configured to: calculate a divide-by value based on which to divide the high-frequency internal clock signal, based on the quantity of pulses; and generate the clock signal by dividing the high-frequency internal clock signal by the divide-by value.

In any one or combination of the embodiments disclosed herein, the system is configured to generate the clock signal further based on a target timing difference between a rising edge of the synchronization clock signal and a rising edge of the clock signal.

Example embodiments of the present disclosure are directed to an apparatus including: a memory having computer readable instructions and one or more processors for executing the computer readable instructions, wherein the computer readable instructions, when executed by the one or more processors, cause the apparatus to: generate a preliminary synchronization clock signal based on a synchronization clock signal, wherein a switching frequency of the preliminary synchronization clock signal is less than a switching frequency of the synchronization clock signal; determine, by a digital controller included in the apparatus, a quantity of pulses of a high-frequency internal clock signal which fit within a first time period during which the preliminary synchronization clock signal is generated; provide the synchronization clock signal to the digital controller during a second time period different from the first time period; and generate a clock signal based on the high-frequency internal clock signal and the quantity of pulses, during the second time period.

In any one or combination of the embodiments disclosed herein, the apparatus is configured to generate the preliminary synchronization clock signal by: providing the synchronization clock signal to a digital counter during the first time period; and generating, by the digital counter, the preliminary synchronization clock signal during the first time period.

In any one or combination of the embodiments disclosed herein, the apparatus is configured to maintain or modify the clock signal based on a frequency of the synchronization clock signal.

In any one or combination of the embodiments disclosed herein, the apparatus is configured to, during the second time period, adjust a frequency of the clock signal such that a duty cycle of a second clock signal derived from synchronizing the clock signal and the synchronization clock signal is about 50 percent.

Additional features and advantages are realized through the techniques of the present disclosure. Other embodiments and aspects of the disclosure are described in detail herein and are considered a part of the claimed technical concept. For a better understanding of the disclosure with the advantages and the features, refer to the description and to the drawings.

### BRIEF DESCRIPTION OF THE SEVERAL VIEWS OF THE DRAWINGS

For a more complete understanding of this disclosure, reference is now made to the following brief description, taken in connection with the accompanying drawings and detailed description, wherein like reference numerals represent like parts.

FIG. 1A illustrates an example of a system that supports digitally synchronizing an internal clock to a synchronization clock in accordance with one or more embodiments of the present disclosure.

FIG. 1B is a plot illustrating waveforms respectively corresponding to the synchronization clock, a clock signal, and an output of the electronic component.

FIG. 1C illustrates an example of a system that supports digitally synchronizing an internal clock to a synchronization clock in accordance with one or more embodiments of the present disclosure.

FIG. 2 illustrates an example flowchart of a method of auto-tuning of clock synchronization in accordance with one or more embodiments of the present disclosure.

FIG. 3 is a table illustrating example aspects of auto-tuning of digitally synchronizing an internal clock to a synchronization clock as supported by the system, digital controller, and the techniques described herein in accordance with one or more embodiments of the present disclosure.

FIG. 4 illustrates an example flowchart of a method clock synchronization in accordance with one or more embodiments of the present disclosure.

FIG. 5 illustrates an example of a system for digital clock synchronization according to some conventional approaches.

### DETAILED DESCRIPTION

A detailed description of one or more embodiments of the disclosed apparatus and method are presented herein by way of exemplification and not limitation with reference to the Figures.

In an electronic system in which several components are operating at the same time or in parallel, a synchronization clock may be provided to the components by an upper system. For example, in a power electronic system in which several power converters are operating at the same time or in parallel, the upper system may provide a synchronization clock to the components. For such cases, some techniques may synchronize the internal clock of each power converter to the external clock by an analog phase locked loop (PLL) or a digital method. In an example, a digital method used by digital controllers (e.g., digital signal processors (DSP) or the like) for synching an internal clock may include premature termination of the clock pulse of the internal clock when the clock pulse (i.e., synch pulse) of the external clock arrives.

Such techniques for synching an internal clock by using premature termination, however, may be problematic for some power converter topologies (e.g., full-bridge power converters) which create two output pulses during a clock period.

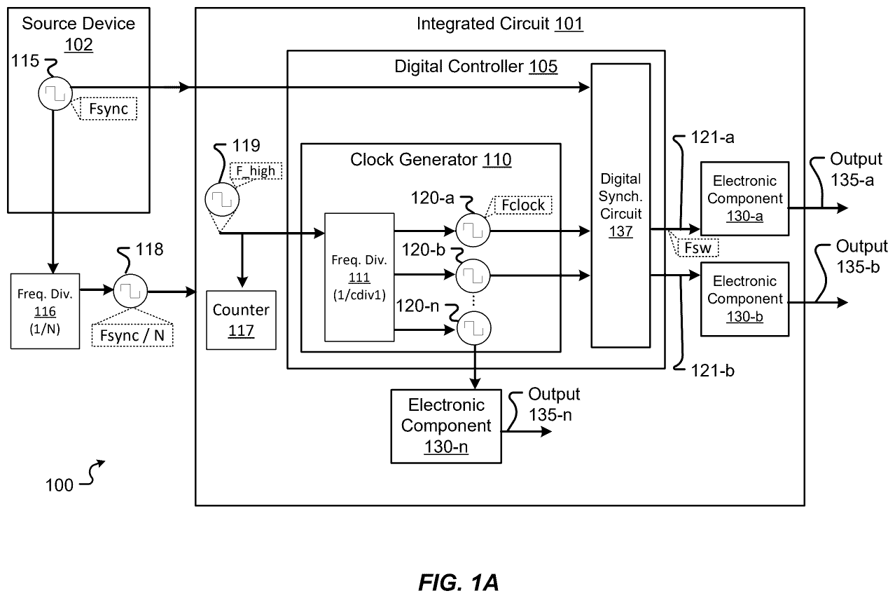

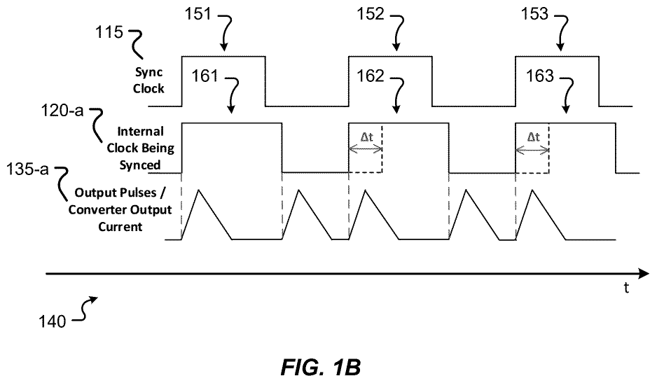

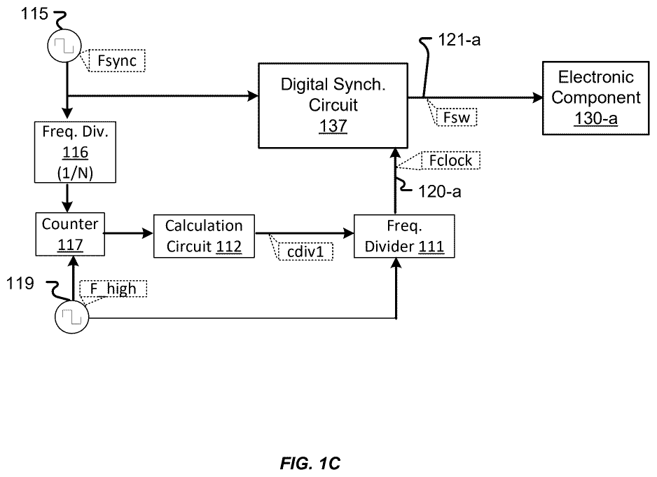

FIG. 1A illustrates an example of a system 100 that supports auto-tuning of digitally synchronizing an internal clock to a synchronization clock in accordance with one or more embodiments of the present disclosure. FIG. 1B is a plot 140 illustrating waveforms processed and/or generated by the system 100 in accordance with one or more embodiments of the present disclosure. FIG. 1C illustrates an example of the system 100 that supports auto-tuning of digitally synchronizing an internal clock to a synchronization clock in accordance with one or more embodiments of the present disclosure.

The system 100 includes an integrated circuit 101. The system 100 may include a source device 102 which is external to and provides a synchronization clock 115 to the integrated circuit 101. In an example, the source device 102 may be or include a crystal oscillator which is coupled to but separate from the digital controller 105, but is not limited thereto. The synchronization clock 115 may be referred to as an external synchronization clock which is relatively highly stable.

The system 100 may divide the synchronization clock 115 using a frequency division circuit 116 (i.e., frequency division) and provide the resultant clock having a reduced frequency to the integrated circuit 101. In some other aspects, the system 100 may provide the synchronization clock 115 to the integrated circuit 101, without dividing the synchronization clock 115. The frequency division circuit 116 may be integrated with or separate from the source device 102. In some embodiments, the frequency division circuit 116 may be integrated with or separate from the integrated circuit 101.

In some alternative and/or additional embodiments, the source device 102, the frequency division circuit 116, and the digital counter 117 may be included in the integrated circuit 101.

The integrated circuit 101 may be, for example, a digital signal processor (DSP), a programmable gate array (PGA), or an application specific integrated circuit (ASIC), but is not limited thereto. The integrated circuit 101 may include a digital controller 105, a clock generator 110, and electronic components 130.

The clock generator 110 may be implemented by circuitry included in the digital controller 105. Some of the electronic components 130 (e.g., electronic component 130-a, electronic component 130-b) may be external to the digital controller 105, and some of the electronic components 130 (e.g., electronic component 130-n) may be included in the digital controller 105. In some embodiments, though not illustrated, some of the electronic components 130 (e.g., electronic component 130-a) may be external to and electrically coupled to the integrated circuit 101.

The digital controller 105 may be referred to as a digital engine herein. In some embodiments, the digital controller 105 may be a digital controller of a power converter, but is not limited thereto.

The digital controller 105 may generate and respectively provide clock signals 120 (e.g., clock signal 120-a to clock signal 120-n) to the digital synchronization circuit 137, and based on synchronization between the clock signals 120 and the synchronization clock 115, provide clock signals 121 to the electronic components 130 (e.g., electronic component 130-a to electronic component 130-n). The digital synchronization circuit 137 may be integrated with or separate from the digital controller 105. In an example, the digital controller 105 may provide clock signal 121-a to electronic component 130-a and/or another electronic component 130 (not illustrated). In another example, the digital controller 105 may provide clock signal 121-b to electronic component 130-b and/or another electronic component 130 (not illustrated). In another example, the digital controller 105 may provide clock signal 121-n to electronic component 130-n and/or another electronic component 130 (not illustrated). The clock signals 120 may be referred to as internal clocks of the integrated circuit 101 or internal clocks of the digital controller 105.

The digital controller 105 may generate the clock signals 120 using the clock generator 110. For example, the clock generator 110 may generate each of the clock signals 120 based on synchronization clock 115. In some embodiments, the synchronization clock 115 may be provided by the source device 102 which is external to the digital controller 105.

In some aspects, (not illustrated), the integrated circuit 101 may include multiple digital controllers 105, each including a respective clock generator 110 capable of generating a respective clock signal 120 in accordance with one or more embodiments of the present disclosure.

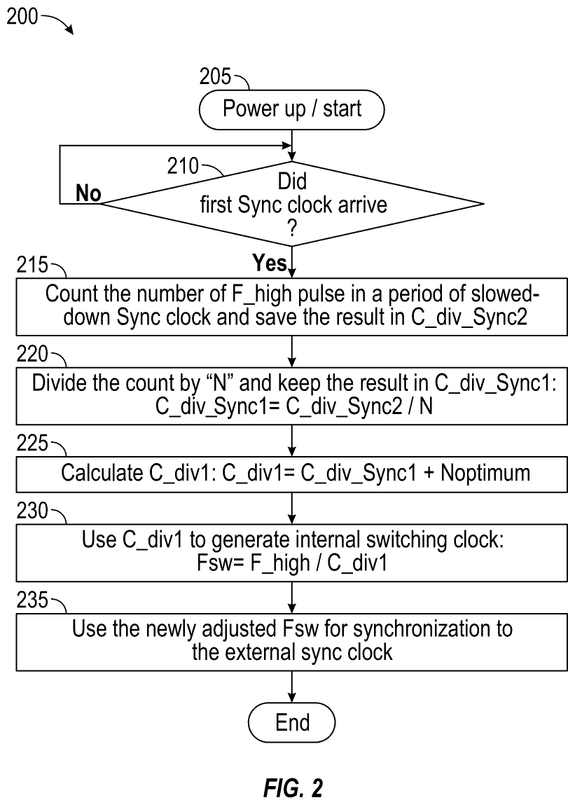

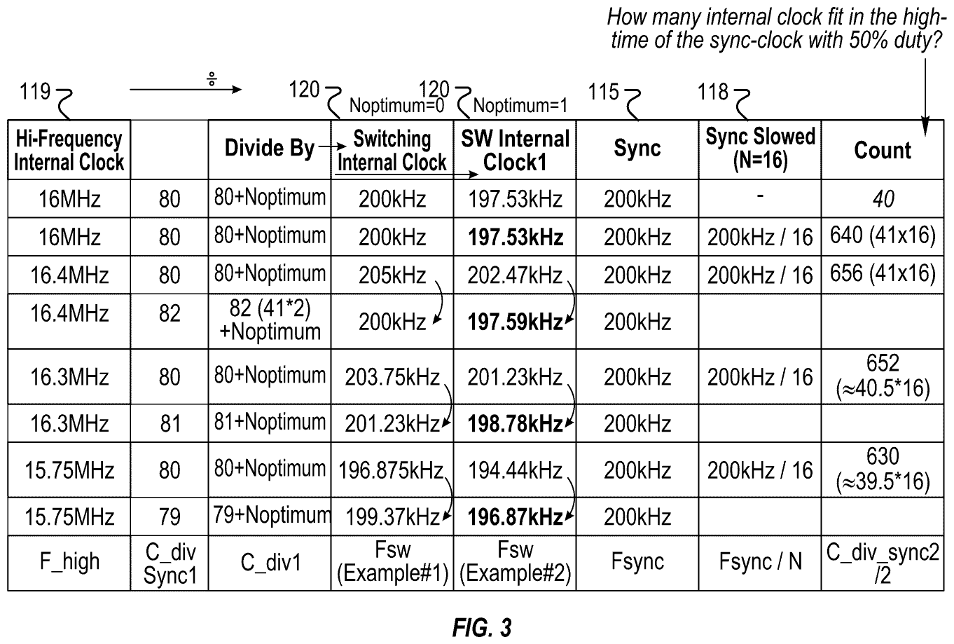

Example aspects of generating a clock signal 120, and further, a clock signal 121 based on synchronization clock 115 in accordance with one or more embodiments of the present disclosure are further described herein with reference to FIG. 1B, FIG. 1C, FIG. 2, and FIG. 3.

The components of the system 100 may be disposed in operable communication with one another. The system 100 supports communication between the integrated circuit 101, the digital controller 105, and other components or devices of the system 100 via wired communication protocols, wireless communication protocols (e.g., electromagnetic (EM) signals, WiFi, Bluetooth™, ZigBee™, Ubiquiti™, 3G, 4G, LTE, and the like), and/or combinations including one or more of the foregoing.

The integrated circuit 101 (and by extension, the digital controller 105) is configured to receive, store and/or transmit data generated from components and devices of the system 100. The integrated circuit 101 includes processing components configured to analyze received data. The integrated circuit 101 includes processing components configured to provide data and/or control signals to other components of the system 100. The integrated circuit 101 may include any number of suitable components, such as processors, memory, communication devices and power sources. The integrated circuit 101 may include processing circuitry capable of executing instructions stored on a memory of (or coupled to) the integrated circuit 101 in association with performing one or more functions described herein.

FIG. 1B is a plot 140 illustrating waveforms respectively corresponding to the synchronization clock 115, clock signal 120-a, and an output 135-a of the electronic component 130-a. With reference to FIG. 1B, the systems and techniques in accordance with one or more embodiments of the present disclosure may prevent or mitigate instances of sub-harmonics being created at an electronic component 130 which is provided a respective clock signal 120. For example, the systems and techniques solve a problem associated with minimizing a Δt between the synchronization clock 115 and the clock signal 120-a.

In an example case in which the electronic component 130-a is a full-bridge power converter, the systems and techniques described herein may prevent or mitigate the creation of a sub-harmonic in the output current/voltage of the electronic component 130-a. For example, embodiments of the present disclosure include setting the frequency of the clock signal 120-a such that, while the digital controller 105 generates a first output pulse 151 in tandem with the clock signal 120-a (internal clock), a second output pulse 152 generated by the digital controller 105 is inside the bounds of a clock pulse 162 of the clock signal 120-a with respect to time t.

In contrast, other approaches for synching an internal clock may include premature termination of the clock pulse of the internal clock by the clock pulse (i.e., synch pulse, as part of a synchronization process) of the synchronization clock (e.g., external clock), which may result in the middle point of the internal clock being missed. Accordingly, for example, a sub-harmonic is created in the output current/voltage of a power converter which is coupled to and operates according to the internal clock.

The systems and techniques described herein as implemented may minimize Δt such that the middle point (e.g., clock pulse 162) of the clock signal 120-a is not missed. Accordingly, for example, by minimizing Δt while keeping Δt positive, the systems and techniques described herein prevent or mitigate instances in which a sub-harmonic is created in the output current/voltage of the electronic component 130-a. In minimizing Δt while keeping Δt positive, the systems and techniques described herein include implementing premature termination of the clock signal 120-a (i.e., internal clock pulse), and further, adjusting the clock signal 120-a at startup such that the clock signal 120-a is very close in frequency to the synchronization clock 115 (i.e., external sync clock).

The systems and techniques described herein include determining and setting a clock frequency (later referenced herein as frequency FSW) for the clock signal 120-a which keeps Δt as small as possible in order to evenly distribute the output pulses of the output 135-a generated by the electronic component 130-a (e.g., a power converter, but not limited thereto) and avoid issues of sub-harmonics and noise. For example, in the case in which the electronic component 130-a is a full bridge power converter, the electronic component 130-a may generate output pulses in response to rising edges and falling edges of the clock signal 120-a.

The systems and techniques described herein include determining and setting a clock frequency and duty cycle for the clock signal 120-a such that the described issues of sub-harmonics and noise are avoided or mitigated.

For example, the systems and techniques described herein may include dividing, using a frequency divider 111, the high-frequency internal clock 119 by a value (‘C_div1’ later described herein) and accordingly generating the clock signal 120-a, such that the frequency of the clock signal 120-a is very close to the external synchronization clock 115 (and smaller than the synchronization clock 115 by a relatively small difference in frequency). The systems and techniques described herein include generating the clock signal 120-a such that the clock signal 120-a is slower than the synchronization clock 115 and close (in frequency value) to the synchronization clock 115, such that the duty cycle of the clock signal 121-a output by the digital synchronization circuit 137 is about 50%. In some aspects, the digital controller 105 may terminate the clock signal 120-a by the rising edge of the synchronization clock 115.

In accordance with one or more embodiments of the present disclosure, to avoid the sub-harmonic and evenly distribute the output pulses of the output 135-a of the electronic component 130-a (e.g., power converter), the digital controller 105 may set the clock signal 120-a such that the clock signal 120-a is as close as possible to the synchronization clock 115. Descriptions herein of a frequency of a clock signal 120 being very close (in frequency value) to the frequency of the synchronization clock 115 such that the clock signal 120-a is slower than the synchronization clock 115 include instances in which rising edges are relatively close to rising edges of the synchronization clock 115 (e.g., based on Δt, duty cycle, and/or other timing or signal characteristics described herein).

For example, the techniques described herein may include providing a high-frequency internal clock 119 having a frequency referred to herein of ‘F_High’ which, in some cases, may be instable. Using the frequency divider 111, the digital controller 105 (digital engine) may divide the high-frequency internal clock 119 down by a division value (also referred to herein as ‘C_div’, ‘C_div1’, or the like), thereby adjusting clock signal 120-a (which is generated by the clock generator 110 based on the high-frequency internal clock 119) such that the frequency of the clock signal 120-a is very close to the frequency of the synchronization clock 115, and further, such that the duty cycle of the clock signal 121- a described herein is about 50%.

The techniques described herein provide a technical improvement when implemented, for example, with respect to digital signal processing. For example, some DSP engines do not accept an extremely high-frequency clock as the main engine clock, and the techniques described herein support correcting the clock signal 120-a (internal clock) made from the high-frequency internal clock 119, such that when the clock signal 120-a is synchronized to synchronization clock 115 (i.e., an external and stable clock), the 50% duty cycle of the clock signal 121- a resulting from the synchronization is substantially or almost maintained (i.e., the duty cycle of clock signal 121-a is about 50%).

The techniques described herein provide a unique way of adjusting the internal frequency of each electronic component 130 close to the synchronization clock 115, for each electronic component 130 (e.g., part/controller) at startup. For example, the techniques described herein may include adjusting the internal frequency for a given electronic component 130 (e.g., electronic component 130-a) such that the internal frequency remains less than and close to the synchronization clock 115. The frequency tuning techniques described herein solve the part-to-part variation issue of the internal clock for a digital controller 105.

An example method of adjusting the internal frequency of an electronic component 130 (i.e., setting the switching frequency Fsw of a clock signal 120 to be provided to the electronic component 130) in accordance with one or more embodiments of the present disclosure is described herein.

The method may include counting the quantity of pulses of the high-frequency internal clock 119 (high-frequency internal pulses) which fit within a period of the synchronization clock 115 at startup. The quantity may be expressed herein as ‘C_div_Sync.’

Next, the digital controller 105 may calculate (e.g., at a ‘C_div’ calculation circuit 112) a value ‘C_div’ based on which the digital controller 105 may divide (using the frequency divider 111) down the high-frequency internal clock 119 having the high frequency F_high to achieve a clock signal 120 that is very close to the synchronization clock 115. In an example, the digital controller 105 may calculate or set ‘C_div’ based on the following Equation (1) and Equation (2):

C_div_sync=C_div−Noptimum (1)

C_div=C_div_Sync+Noptimum (2)

The method may include setting the value ‘Noptimum’ based on target tolerances. For example, the method may include setting the value ‘Noptimum’ such that Δt is positive and minimum (e.g., less than or equal to a threshold Δt value) considering all tolerances. For example, for a relatively higher tolerance, the method may include setting a relatively larger value ‘Noptimum’, and the threshold Δt value (worst case Δt) will be higher.

In some embodiments, to provide increased accuracy, the method may include providing (e.g., by an upper system) a lower frequency synchronization clock for a relatively short period of time at startup. For example, the method may include dividing the frequency Fsync of the synchronization clock 115 by N (e.g., Fsync/N), using the frequency division circuit 116, thereby outputting a preliminary synchronization clock 118 having a lowered frequency of Fsync/N. The digital controller 105 may perform the described operations of calculating the value ‘C_div_Sync’, setting the value ‘Noptimum’, and calculating the value ‘C_div’ during this period of time based on the preliminary synchronization clock 118 (i.e., the lower frequency synchronization clock) and, accordingly, for example, adjust the clock signal 120 (internal switching clock) with increased accuracy.

The techniques described herein provide auto-tuning which compensates for the variations of the high-frequency internal clock 119 (having frequency F_high) from one digital controller 105 to another. As described herein, the techniques include performing auto-tuning after the power up of the digital controller 105 and when the first clock pulses of the synchronization clock 115 arrive at the digital controller 105.

An example implementation in which the digital controller 105 is a digital controller of a power converter is described herein. For a digital controller of a power converter, there is a high-frequency internal clock (having a frequency F_high), which is divided down by a digital counter to generate the switching clock (having a switching frequency Fsw).

The digital controller 105 divides F_high by the number C_div to generate the desired switching frequency Fsw. For example, if during the switching period Tsw (=1/Fsw), the number of clock pulses of the high-frequency clock (having the frequency F_high) are counted, the result will be C_div.

Since Fsw<Fsync, an associated period Tsync (=1/Fsync) will be smaller than Tsw. Under an assumption that FSync is accurate, if during the period of Tsync, the number of clock pulses of the high-frequency clock (having the frequency F_high) pulses are counted, the number C_div_sync will be smaller than C_div. A target value for C_div_sync is given by Equation (1) from above:

C_div_sync=C_div−Noptimum (1)

FIG. 2 illustrates an example flowchart of a method 200 of auto-tuning of clock synchronization in accordance with one or more embodiments of the present disclosure. The method 200 may be implemented by an integrated circuit 101 and digital controller 105 as described herein. The method 200 supports auto-tuning of digitally synchronizing a clock signal 120 (e.g., clock signal 120-a, clock signal 120-n, or the like) of a clock for an electronic component 130 (e.g., electronic component 130-a, electronic component 130-n, or the like) to a synchronization clock 115 in accordance with one or more embodiments of the present disclosure.

At block 205, the method 200 includes powering up or starting the digital controller 105. With respect to powering up the digital controller 105, the method 200 includes applying the power to the digital controller 105 and, after a minimum predetermined amount of time for the boot up of the digital controller 105, sending the synchronization clock 115.

At block 210, the method 200 includes determining whether the synchronization clock 115 has arrived. The method 200 may include repeating the operations of block 210 until determining the synchronization clock 115 has arrived (‘Yes’), at which the method 200 may include proceeding to block 215.

At block 215, the method 200 includes counting the quantity of pulses of the high-frequency internal clock 119 (having frequency F_high) in a period in which the synchronization clock 115 is slowed down. The synchronization clock 115 during the period in which the synchronization clock 115 is slowed down may be referred to as a preliminary synchronization clock 118.

For example, the method 200 may include counting, by the digital counter 117, the quantity of pulses of high-frequency internal clock 119 during a time period in which the synchronization clock 115 is divided by N (i.e., Fsync/N, as implemented by the frequency division circuit 116). At block 215, the method 200 includes saving the resulting quantity (also expressed herein as a count ‘C_div_Sync2’).

At block 220, the method 200 includes calculating a value ‘C_div_Sync1’ based on the following Equation (3), which divides the count ‘C_div_Sync2’ by ‘N’:

C_div_sync1=C_div_Sync2/N (3)

At block 225, the method 200 includes calculating a division value ‘C_div1’ (also referred to herein as a ‘Divide By’ value) for later determining the target internal switching frequency (‘Fsw’) for the clock signal 120 for the electronic component 130. In an example, the method 200 includes calculating the division value ‘C_div1’ based on the following Equation (4):

C_div1=C_div_Sync1+Noptimum (4)

At block 230, the method 200 includes using the division value ‘C_div1’ to generate a clock signal 120 having a switching frequency Fsw for the electronic component 130, using the following Equation (5):

Fsw=F_high/C_div1 (5)

At block 235, the method 200 includes using the newly adjusted switching frequency Fsw for synchronization of the clock signal 120 to the synchronization clock 115. For example, the method 200 includes providing the clock signal 120 having the switching frequency Fsw to the electronic component 130.

Aspects of the equations which support the techniques described herein are now further described.

With reference to Equation (2):

C_div=C_div_sync+Noptimum (2)

For a case of a digital controller 105 with a very accurate high-frequency internal clock 119 (having a frequency F_high) provided by an internal source device (e.g., a crystal oscillator) of the digital controller 105, Equation (2) holds. However, if the parts/controllers have a high part-to-part variation with respect to the frequency F_high of the high-frequency internal clock 119, then counting the high-frequency pulses during the period (Tsync) of the synchronization clock 115 will result in a different C_div_sync value, which may be referred to as ‘C_dic_sync1’.

If C_div is modified to the new value of C_div1 given by the following Equation (2.1), then the internal switching frequency Fsw of clock signal 120 will be very close to Fsync:

C_div1=C_div_sync1+Noptimum (2.1)

Therefore, the Δt will be positive and minimum, such that the first half cycle and the second half cycle of the switching period will be very similar to one another (i.e., in terms of timing, such that the duty cycle of the clock signal 120 is about 50%). Therefore, the described problems of sub-harmonic may be avoided.

As previously described, to increase the accuracy in the counting of the pulses (F_high pulses) of the high-frequency internal clock 119, embodiments of the present disclosure include sending the synchronization clock 115 (system clock) with a lower frequency at the beginning (i.e., sending preliminary synchronization clock 118 having a frequency of Fsync/N, in which N is an integer value greater than 1). Sending the synchronization clock 115 according to a lower frequency increases the accuracy of the auto tuning system. After counting the pulses (F_high pulses) of the high-frequency internal clock 119, the techniques described herein include reverting the synchronization clock 115 back to normal frequency (i.e., Fsync) before powering on the electronic component 130 (e.g., power converter) to which the clock signal 120 will be provided.

In a non-limiting example, the techniques described herein may include an initial period of frequency dividing the synchronization clock 115 by of 1/N (e.g. N=16) using the frequency division circuit 116 and sending 10 pulses of the synchronization clock 115 according to the lowered frequency of 1/N (i.e., sending 10 pulses of the preliminary synchronization clock 118 having the lowered frequency of Fsync/N). During the initial period, the techniques described herein include performing the auto tuning calculations. This will result in a count value of ‘C_div_Sync2’.

The techniques described herein further include dividing the count value ‘C_div_Sync2’ by N (where N=16) and incorporating the result, as in the following Equation (6):

C_div1=C_div_sync2/N+Noptimum (6)

FIG. 3 is a table 300 illustrating example aspects of auto-tuning of digitally synchronizing an internal clock to a synchronization clock as supported by the system 100, digital controller 105, and the techniques described herein in accordance with one or more embodiments of the present disclosure.

Non-limiting examples of F_high, C_div_Sync1, C_div1, Fsw (according to a first example), Fsw (according to a second example), count values, and C_div_Sync2 described herein with respect to auto-tuning of digitally synchronizing an internal clock to a synchronization clock are illustrated at table 300.

The techniques described herein for auto-tuning of digitally synchronizing an internal clock to a synchronization clock solve problems for cases in which a digital controller, which may either have a very stable internal frequency or use an external high-frequency clock as the main engine clock, is not readily available for a particular electronic design. For example, some other approaches may include providing a digital controller and further adding a trimming step in the production to adjust the internal frequency of the digital controller for each module. However, such approaches may not be practical due to factors such as, for example, design constraints, added production cost, or manufacturing constraints.

The techniques described herein may provide technical improvements for power converter applications, but are not limited thereto. For example, for cases in which several power converters operate in a system, and particularly, when there are two or more power converters in parallel, the techniques described herein may support effective synchronization of the switching action of each power converter to a single synchronization clock.

In some approaches, the synchronization clock is a very stable external clock which is provided by the upper-level system to each and every power converter of the system, and the power converters use their local phased locked loop (PLL) to synchronize themselves to the synchronization clock. For some power converter topologies, the synchronization action is simple, and the internal switching clock is synchronized, for example, by a digital PLL or an analog PLL, to the external clock.

However, synchronization for some other power converter topologies, such as, for example, full-bridge power converters may be relatively more complex. For example, during each half cycle of the controller clock for a full-bridge power converter, one pulse is generated at the output. Accordingly, the output frequency of a full-bridge power converter may be twice the input frequency of the PWM circuit coupled to the full-bridge power converter.

For such full-bridge power converters, target performance specifications include that the duty cycle of the converter clock be very close to 50% (e.g., about 50%, with a predetermined tolerance) so as to ensure that the distance between the output pulses of the power converter remain equal and sub-harmonic is prevented.

For implementations of a power converter controller in which the frequency of the internal clock is to be half the frequency of the output of the full-bridge power converter, then to prevent a sub-harmonic, it may be desired that the switching period of the synchronization clock is symmetrically divided into two equal periods by the power converter controller.

When such a full-bridge power converter is synchronized with an external clock, providing a synchronization scheme which ensures that the 50% duty cycle of the synchronized clock is maintained is desired for proper operation of the full-bridge power converter. In some approaches, maintaining the 50% duty cycle may be achieved with analog synchronization schemes (e.g., analog PLLs).

Digital synchronization, in some cases, may be accomplished by adjusting the internal clock of the power converter controller (e.g., a digital PLL) to have a frequency slightly lower (e.g., by a predetermined amount) than the frequency of the system synchronization clock. Accordingly, for example, every time the synchronization clock arrives, the cycle of the internal clock is terminated prematurely. As a result, with some digital PLLs, if the difference between the frequency of the internal clock of the digital PLL and the frequency of the synchronization clock is considerable (e.g., based on a threshold value), then the duty cycle of the resultant clock will significantly deviate from 50%. The problem with the described digital synchronization methods using digital PLLs (unlike analog PLLs) is that the first half cycle of the internal clock is a little longer (based on time) than the second half cycle of the clock. And as explained herein, this difference between the half cycles causes a sub-harmonic problem with power converter topologies such as full-bridge power converters.

The techniques described herein for auto-tuning of digitally synchronizing an internal clock to a synchronization clock solve problems for cases in which the internal frequency of a power converter is much different than the frequency of a synchronization clock. For example, the distance between the output pulses of the power converter for such cases will not remain equal for each half-cycle, which causes sub-harmonic and noise problems. To solve the sub-harmonic and noise problems, some approaches may include adjusting the internal frequency of the power converter to be lower than but very close to the synchronization clock. However, such approaches may still result in sub-harmonic and noise problems for cases in which the variation of the internal clock of the converter exceeds a threshold (e.g., due to temperature variations, part-to-part variations, or the like).

For cases in which the variation in the internal frequency of the power converter exceeds a threshold variation value, the techniques described herein support adjusting the initial frequency such that, considering variations in the internal frequency (e.g., due to temperature variations, part-to-part variations, worst case scenarios, or the like), the internal frequency always remains smaller than the synchronization clock frequency. For example, in a worst-case scenario, the internal frequency may be adjusted lower than the synchronization clock frequency and the difference would be negligible.

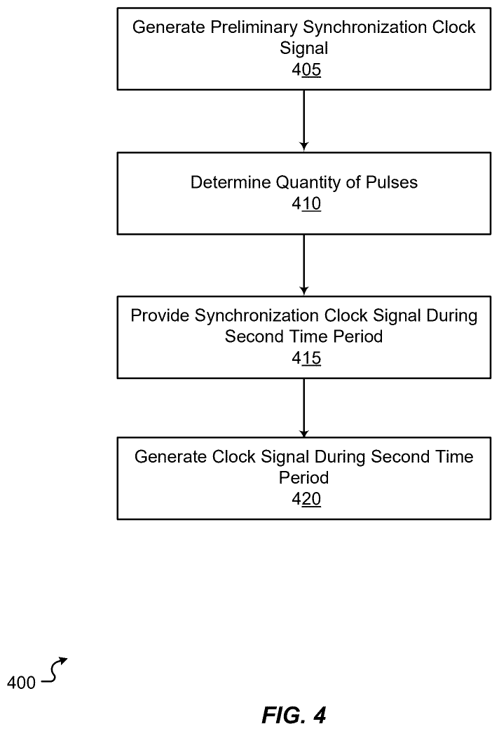

FIG. 4 illustrates an example flowchart of a method 400 of auto-tuning of clock synchronization in accordance with one or more embodiments of the present disclosure. The method 400 may be implemented by the example aspects of a system 100 described herein.

At block 405, the method 400 includes generating a preliminary synchronization clock signal based on a synchronization clock signal, wherein a switching frequency of the preliminary synchronization clock signal is less than a switching frequency of the synchronization clock signal.

At block 410, the method 400 includes determining, by a digital controller, a quantity of pulses of a high-frequency internal clock signal which fit within a first time period during which the preliminary synchronization clock signal is generated.

At block 415, the method 400 includes providing the synchronization clock signal to the digital controller during a second time period different from the first time period.

At block 420, the method 400 includes generating, by the digital controller, a clock signal based on the high-frequency internal clock signal and the quantity of pulses, during the second time period.

In some aspects, generating the preliminary synchronization clock signal includes: providing the synchronization clock signal to a digital counter during the first time period; and generating, by the digital counter, the preliminary synchronization clock signal during the first time period.

In some aspects, the method further includes maintaining or modifying the clock signal based on a frequency of the synchronization clock signal.

In some aspects, the method further includes during the second time period, adjusting a frequency of the clock signal such that a duty cycle of a second clock signal derived from synchronizing the clock signal and the synchronization clock signal is about 50 percent.

In some aspects, the method further includes providing the clock signal to a full bridge power converter.

In some aspects, a frequency of the clock signal is less than a frequency of the synchronization clock signal.

In some aspects, the method further includes: calculating a divide-by value based on which to divide the high-frequency internal clock signal, based on the quantity of pulses, wherein generating the clock signal includes dividing the high-frequency internal clock signal by the divide-by value.

In some aspects, generating the clock signal is further based on a target timing difference between a rising edge of the synchronization clock signal and a rising edge of the clock signal.

In the descriptions of the flowcharts herein, the operations may be performed in a different order than the order shown, or the operations may be performed in different orders or at different times. Certain operations may also be left out of the flowcharts, one or more operations may be repeated, or other operations may be added to the flowcharts.

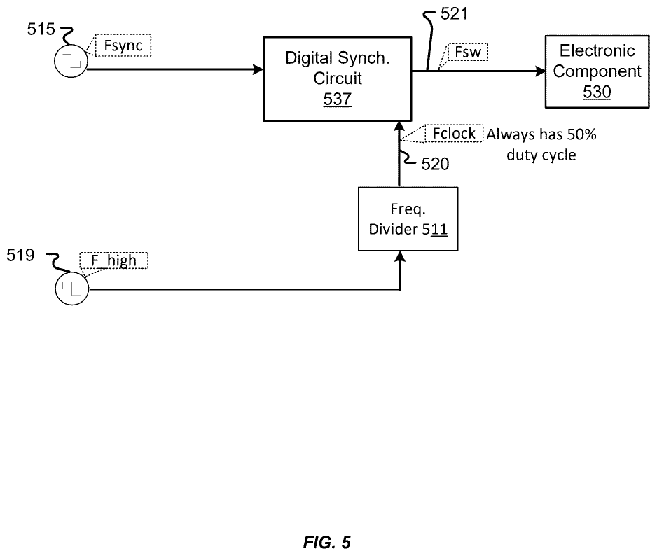

FIG. 5 illustrates an example of a system 500 for digital clock synchronization according to some conventional approaches. The techniques described herein solve problems associated with conventional digital synchronization approaches as illustrated at FIG. 5, as such conventional digital synchronization approaches are based on premature termination of an internal clock (e.g., an internal clock 520, which has a 50% duty cycle) when a synchronization clock (e.g., synchronization clock 515) arrives. For example, in some other approaches as in FIG. 5, when the frequency F_high of a high-frequency internal clock 519 changes from part-to-part and is not stable, the duty cycle of clock signal 521 may change (e.g., deviate from 50%).

The term “about” is intended to include the degree of error associated with measurement of the particular quantity based upon the equipment available at the time of filing the application.

The terminology used herein is for the purpose of describing particular embodiments only and is not intended to be limiting of the present disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

While the present disclosure has been described with reference to an exemplary embodiment or embodiments, it will be understood by those skilled in the art that various changes may be made and equivalents may be substituted for elements thereof without departing from the scope of the present disclosure. In addition, many modifications may be made to adapt a particular situation or material to the teachings of the present disclosure without departing from the essential scope thereof. Therefore, it is intended that the present disclosure not be limited to the particular embodiment disclosed as the best mode contemplated for carrying out this present disclosure, but that the present disclosure will include all embodiments falling within the scope of the claims.

The corresponding structures, materials, acts and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the technical concepts in the form disclosed. Many modifications and variations will be apparent to those of ordinary skill in the art without departing from the scope and spirit of the disclosure. The embodiments were chosen and described in order to best explain the principles of the disclosure and the practical application and to enable others of ordinary skill in the art to understand the disclosure for various embodiments with various modifications as are suited to the particular use contemplated.

While the various embodiments to the disclosure have been described, it will be understood that those skilled in the art, both now and in the future, may make various improvements and enhancements which fall within the scope of the claims which follow. These claims should be construed to maintain the proper protection for the disclosure first described.

What is claimed is:

1. A method of tuning of clock synchronization comprising:
generating a preliminary synchronization clock signal based on a synchronization clock signal, wherein a switching frequency of the preliminary synchronization clock signal is less than a switching frequency of the synchronization clock signal;
determining, by a digital controller, a quantity of pulses of a high-frequency internal clock signal which fit within a first time period during which the preliminary synchronization clock signal is generated;
providing the synchronization clock signal to the digital controller during a second time period different from the first time period; and
generating, by the digital controller, a clock signal based on the high-frequency internal clock signal and the quantity of pulses, during the second time period.

2. The method of claim 1, wherein generating the preliminary synchronization clock signal comprises:
providing the synchronization clock signal to a digital counter during the first time period; and
generating, by the digital counter, the preliminary synchronization clock signal during the first time period.

3. The method of claim 1, further comprising maintaining or modifying the clock signal based on a frequency of the synchronization clock signal.

4. The method of claim 1, further comprising, during the second time period, adjusting a frequency of the clock signal such that a duty cycle of a second clock signal derived from synchronizing the clock signal and the synchronization clock signal is about 50 percent.

5. The method of claim 1, further comprising providing the clock signal to a full bridge power converter.

6. The method of claim 1, wherein a frequency of the clock signal is less than a frequency of the synchronization clock signal.

7. The method of claim 1, further comprising:
calculating a divide-by value based on which to divide the high-frequency internal clock signal, based on the quantity of pulses,
wherein generating the clock signal comprises dividing the high-frequency internal clock signal by the divide-by value.

8. The method of claim 7, wherein generating the clock signal is further based on a target timing difference between a rising edge of the synchronization clock signal and a rising edge of the clock signal.

9. A system configured to:
generate a preliminary synchronization clock signal based on a synchronization clock signal, wherein a switching frequency of the preliminary synchronization clock signal is less than a switching frequency of the synchronization clock signal;
determine, by a digital controller comprised in the system, a quantity of pulses of a high-frequency internal clock signal which fit within a first time period during which the preliminary synchronization clock signal is generated;
provide the synchronization clock signal to the digital controller during a second time period different from the first time period; and
generate a clock signal based on the high-frequency internal clock signal and the quantity of pulses, during the second time period.

10. The system of claim 9, wherein the system is configured to generate the preliminary synchronization clock signal by:
providing the synchronization clock signal to a digital counter during the first time period; and
generating, by the digital counter, the preliminary synchronization clock signal during the first time period.

11. The system of claim 9, wherein the system is configured to maintain or modify the clock signal based on a frequency of the synchronization clock signal.

12. The system of claim 9, wherein the system is configured to, during the second time period, adjust a frequency of the clock signal such that a duty cycle of a second clock signal derived from synchronizing the clock signal and the synchronization clock signal is about 50 percent.

13. The system of claim 9, wherein the system is configured to provide the clock signal to a full bridge power converter.

14. The system of claim 9, wherein a frequency of the clock signal is less than a frequency of the synchronization clock signal.

15. The system of claim 9, wherein the system is configured to:
calculate a divide-by value based on which to divide the high-frequency internal clock signal, based on the quantity of pulses; and
generate the clock signal by dividing the high-frequency internal clock signal by the divide-by value.

16. The system of claim 15, wherein the system is configured to generate the clock signal further based on a target timing difference between a rising edge of the synchronization clock signal and a rising edge of the clock signal.

17. An apparatus comprising:
a memory having computer readable instructions and one or more processors for executing the computer readable instructions, wherein the computer readable instructions, when executed by the one or more processors, cause the apparatus to:
generate a preliminary synchronization clock signal based on a synchronization clock signal, wherein a switching frequency of the preliminary synchronization clock signal is less than a switching frequency of the synchronization clock signal;
determine, by a digital controller comprised in the apparatus, a quantity of pulses of a high-frequency internal clock signal which fit within a first time period during which the preliminary synchronization clock signal is generated;
provide the synchronization clock signal to the digital controller during a second time period different from the first time period; and
generate a clock signal based on the high-frequency internal clock signal and the quantity of pulses, during the second time period.

18. The apparatus of claim 17, wherein the apparatus is configured to generate the preliminary synchronization clock signal by:
providing the synchronization clock signal to a digital counter during the first time period; and
generating, by the digital counter, the preliminary synchronization clock signal during the first time period.

19. The apparatus of claim 17, wherein the apparatus is configured to maintain or modify the clock signal based on a frequency of the synchronization clock signal.

20. The apparatus of claim 17, wherein the apparatus is configured to, during the second time period, adjust a frequency of the clock signal such that a duty cycle of a second clock signal derived from synchronizing the clock signal and the synchronization clock signal is about 50 percent.
